(19) United States
(12) Patent Application Publication
(10) Pub. No.: US 2026/0227253 A1
(43) Pub. Date: Aug. 6, 2026

(54) STRESS AND STRAIN DETECTION ACROSS A SUBSTRATE OF A SEMICONDUCTOR SYSTEM USING A PHOTOELASTIC MATERIAL

(71) Applicant: Micron Technology, Inc., Boise, ID (US)

(72) Inventors: Manish Nayini, Hyderabad (IN); Pavankumar Umesh Vibhute, Hyderabad (IN); Bhaskar Rao Korpati, Hyderabad (IN); Ramesh Nallavelli, Hyderabad (IN); Nagavenkata Varaprasad Nune, Hyderabad (IN)

(21) Appl. No.: 19/445,059

(22) Filed: Jan. 9, 2026

Related U.S. Application Data
(60) Provisional application No. 63/751,121, filed on Jan. 29, 2025.

(51) Int. Cl. G01L 1/24; H05K 1/02

(52) U.S. Cl. CPC G01L 1/241; H05K 1/0298; H05K 2201/10159; H05K 2201/2081

(57) ABSTRACT

Methods, systems, and devices for stress and strain detection across a substrate of a semiconductor system using a photoelastic material are described. In some examples, a semiconductor system may include a memory module having at least one segment of a photoelastic material over and/or on a substrate of the memory module. In some examples, the segment is located proximate an area of the substrate that is subject to a stress and/or strain condition during insertion of the memory module (e.g., an edge connector of the memory module) into a socket. The photoelastic material may be configured improve detection and/or monitoring of stresses on the memory module.

### CROSS REFERENCE

The present Application for Patent claims priority to U.S. Patent Application No. 63/751,121 by Nayini et al., entitled “STRESS AND STRAIN DETECTION ACROSS A SUBSTRATE OF A SEMICONDUCTOR SYSTEM USING A PHOTOELASTIC MATERIAL,” filed January 29, 2025, which is assigned to the assignee hereof, and which is expressly incorporated by reference in its entirety herein.

### TECHNICAL FIELD

The following relates to one or more systems for memory, including stress and strain detection across a substrate of a semiconductor system using a photoelastic material.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports stress and strain detection across a substrate of a semiconductor system using a photoelastic material in accordance with examples as disclosed herein.

FIG. 2 shows an example of a memory module that supports stress and strain detection across a substrate of a semiconductor system using a photoelastic material in accordance with examples as disclosed herein.

FIG. 3 shows example geometric features that support stress and strain detection across a substrate of a semiconductor system using a photoelastic material in accordance with examples as disclosed herein.

FIG. 4 shows example manufacturing operations that support stress and strain detection across a substrate of a semiconductor system using a photoelastic material in accordance with examples as disclosed herein.

FIG. 5 shows an example socketing operation that supports stress and strain detection across a substrate of a semiconductor system using a photoelastic material in accordance with examples as disclosed herein.

FIG. 6 shows an example manufacturing line that supports stress and strain detection across a substrate of a semiconductor system using a photoelastic material in accordance with examples as disclosed herein.

FIGS. 7 and 8 show flowcharts illustrating a method or methods that support stress and strain detection across a substrate of a semiconductor system using a photoelastic material in accordance with examples as disclosed herein.

### DETAILED DESCRIPTION

An integrated assembly (e.g., a memory module) may include a substrate populated with one or more semiconductor devices. In some cases, inserting an edge connector of the substrate into a socket may induce stresses across the integrated assembly. The stresses may induce quality and/or reliability defects to the integrated assembly, such as cracking in solder joints used to mount the semiconductor devices to the substrate and/or cracking in other portions of the substrate (e.g., traces that are routed through the substrate).

In some cases, methods to detect and/or monitor stresses during insertion of the edge connector into the socket are cumbersome and may include instrumenting the substrate with strain gauges, among other examples. Such methods may be constrained to a lab environment and/or low volume conditions (e.g., qualification and/or sampling phases of product development), and are not useable by a consumer of the integrated assembly or in a high volume manufacturing (HVM) environment.

In accordance with examples as described herein, a memory system may include a memory module having at least one segment of a photoelastic material over and/or on a substrate of the memory module. In some examples, the segment is located proximate an area of the substrate that is subject to a stress and/or strain condition during insertion of the memory module (e.g., an edge connector of the memory module) into a socket. The photoelastic material may be configured to improve detection and/or monitoring of stresses on the memory module.

In some examples, the segment is over and/or on a solder mask layer that is that is over and/or on a surface of the substrate. During insertion of the module into the socket, an optical inspection tool that detects a birefringent condition in the segment may be used as part of detecting a stress and/or a strain condition in memory module.

Techniques described herein may be used to adjust a mechanical load associated with socketing of a memory module to improve a quality and/or a reliability of the memory module. The techniques may be less complex than other techniques that rely on strain gauges and/or other instrumentation, and thereby be more efficient. Additionally, or alternatively, the techniques may be scalable to HVM environments to increase a sampling population and improve an overall statistical evaluation of stress and/or strain conditions experienced for a product line of apparatuses that include the integrated assembly.

In addition to applicability in memory systems as described herein, techniques for stress and/or strain detection across a substrate of a semiconductor system using a photoelastic material may be generally implemented to support increased connectivity of electronic systems. As the use of systems relying on interconnected electronic devices increases, the connectivity of these electronic devices becomes an increasingly relevant factor for the operations of the system. For example, delays and/or interruptions associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by reducing cracking in solder joints that connect semiconductor devices to the substrate and/or cracking in traces of the substrate, among other benefits.

Features of the disclosure are illustrated and described in the context of systems and architectures. Features of the disclosure are further illustrated and described in the context of a semiconductor system, a memory module including a substrate, example configurations of segments of a photoelastic material, manufacturing techniques that may be used to form a segment of the photoelastic material over and/or on the substrate, birefringence techniques that may use a segment the photoelastic material to detect a stress and/or a strain condition, and flowcharts.

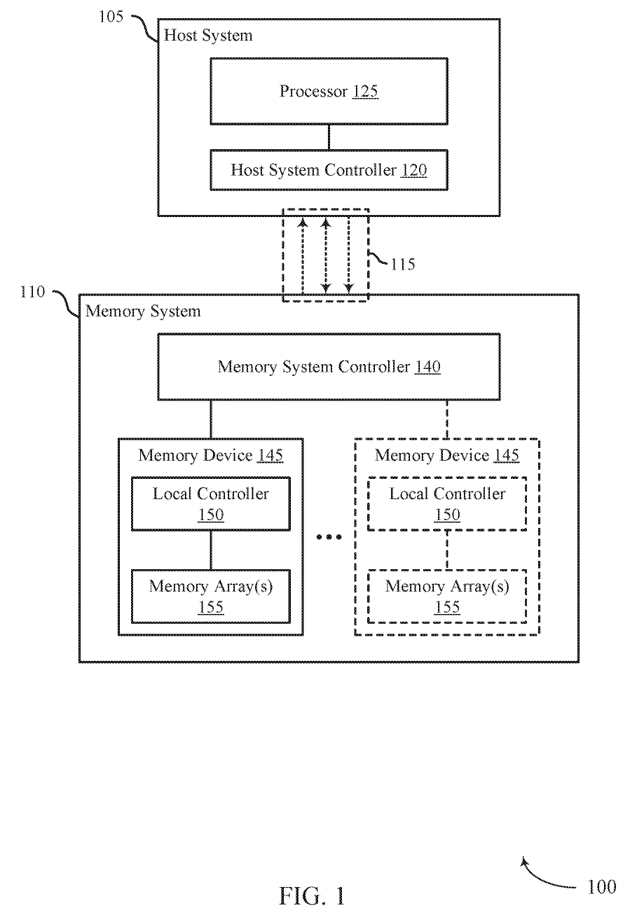

FIG. 1 shows an example of a system 100 that supports stress and strain detection across a substrate of a semiconductor system using a photoelastic material in accordance with examples as disclosed herein. The system 100 (e.g., a semiconductor system) may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

A host system 105 may include one or more components (e.g., circuitry, processing circuitry, application processing circuitry, one or more processing components) that use memory to execute processes (e.g., applications, functions, computations), any one or more of which may be referred to as or be included in a processor 125 (e.g., an application processor). A processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. A processor 125 may be an example of a central processing unit (CPU), a graphics processing unit (GPU), a general-purpose GPU (GPGPU), or an SoC or a component thereof, among other examples.

A host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating a memory system 110, such as write commands, read commands, configuration signaling or other operational signaling. In some examples, a host system controller 120, or associated functions described herein, may be implemented by or be part of a processor 125. For example, a host system controller 120 may be hardware, instructions (e.g., software, firmware), or a combination thereof implemented by a processor 125 or other component of a host system 105. In various examples, a host system 105 or a host system controller 120 may be referred to as a host.

A memory system 110 provides physical memory locations (e.g., addresses) that may be used or referenced by the system 100. A memory system 110 may include a memory system controller 140 and one or more memory devices 145 (e.g., memory packages, memory dies, portions of a memory die) operable to store data. A memory system 110 may be configurable for operations with different types of host systems 105, and may respond to commands from the host system 105 (e.g., from a host system controller 120). For example, a memory system 110 (e.g., a memory system controller 140) may receive a write command indicating that the memory system 110 is to store data received from a host system 105, or receive a read command indicating that the memory system 110 is to provide data stored in a memory device 145 to a host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of a semiconductor system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with a host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 (e.g., a logic controller, an interface controller, one or more processors) and one or more memory arrays 155. A memory array 155 may be a collection of memory cells (e.g., a two-dimensional array, a three-dimensional array, an array of one or more semiconductor components), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a semiconductor system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a semiconductor system 110.

A host system 105 (e.g., a host system controller 120) and a memory system 110 (e.g., a memory system controller 140) may communicate information (e.g., data, commands, control information, configuration information, timing information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. In some implementations, at least the channels 115 between a host system 105 and a memory system 110 may include or be referred to as a host interface (e.g., a physical host interface). To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 may be dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

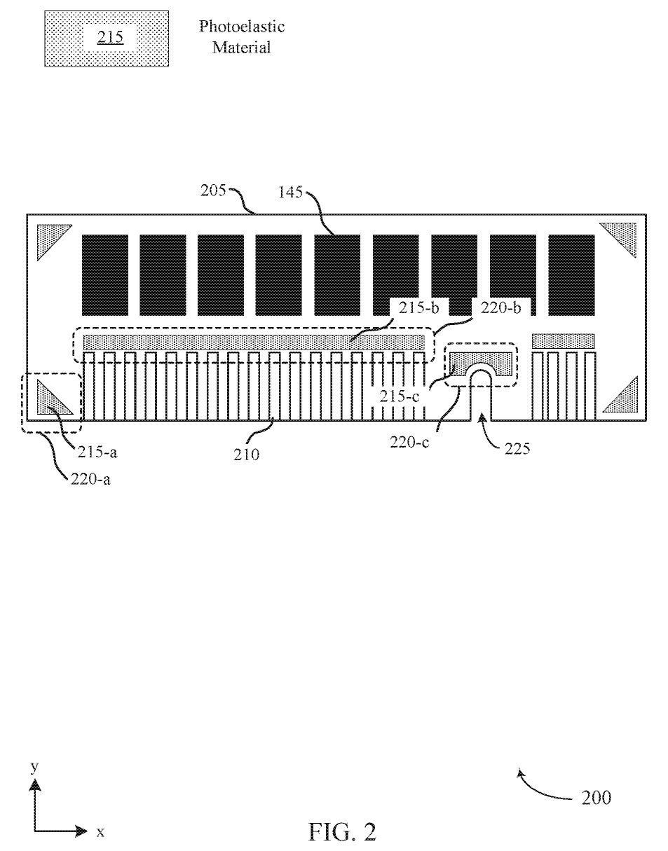

As described in greater detail in connection with FIGS. 2 through 7, the memory system controller 140 and/or the memory device 145 may be part of a memory module (a dual-in line memory module (DIMM) including DRAM memory or a solid state drive (SSD) including NAND memory, among other examples). In some examples, one or more segments of a photoelastic material may be affixed to a substrate of the module to detect stress and/or strain conditions during manufacturing of the memory module.

FIG. 2 shows an example of a memory module 200 that supports stress and strain detection across a substrate of a semiconductor system using a photoelastic material in accordance with examples as disclosed herein. FIG. 2 is a plan view in an x-y plane showing at least a portion of the memory module 200. In some examples, the memory module 200 may be part of a semiconductor system (e.g., the system 100 including the memory system 110 as described in connection with FIG. 1).

As shown in FIG. 2, the memory module 200 includes a substrate 205. In some examples, the substrate 205 may be a multi-layer substrate. Additionally, or alternatively, and in some examples, the substrate 205 may be a printed circuit board (PCB) including one or more layers of a conductive material (e.g., copper or aluminum) interspersed with one or more layers of a dielectric material (e.g., epoxy resin). Additionally, or alternatively, and in some examples, the substrate 205 may be a ceramic substrate including one or more layers of a conductive material interspersed with one or more layers of ceramic.

As further shown in FIG. 2, the substrate 205 is populated with at least one memory device 145 as described in connection with FIG. 1. The memory device 145 may be coupled with traces and or pads of the substrate 205 via one or more connection structures that are conductive (bumps, solder balls, or pillars formed from copper, tin, silver, gold, and/or nickel among other examples). In some examples, the memory device 145 may be encapsulated in a semiconductor package. Alternatively, and in some other examples, the memory device 145 may be a bare die (e.g., a flipchip die).

As further shown in FIG. 2, the substrate 205 includes at least one conductive pad 210 (e.g., an exposed pad formed from a conductive layer of the substrate) proximate an edge of the substrate. The conductive pad 210 may be one of multiple, substantially similar pads that in combination form an edge connector along the edge of the substrate 205.

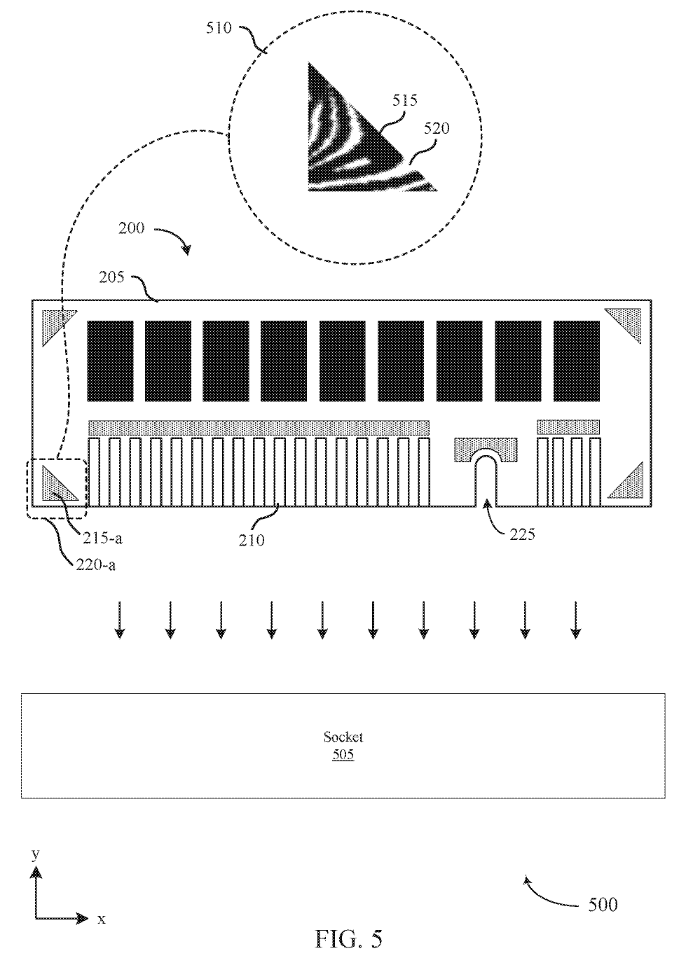

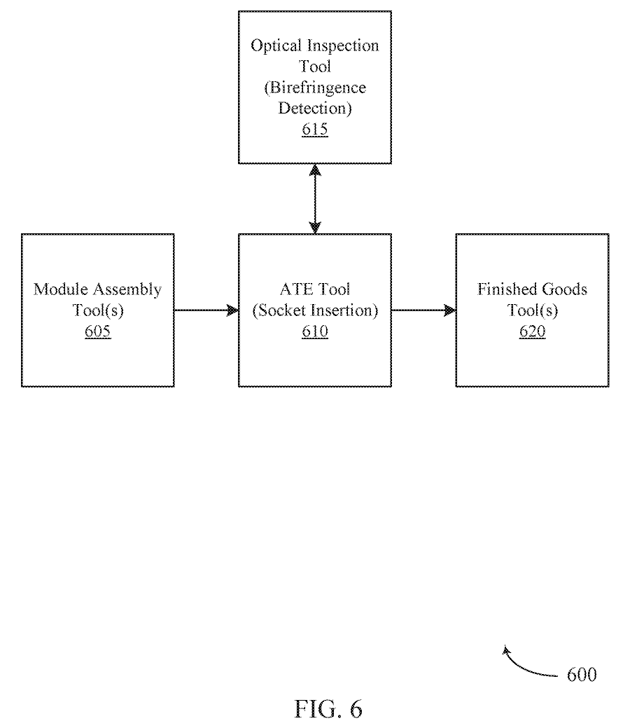

As further shown in FIG. 2, one or more segments 215 of a photoelastic material may be positioned over the substrate 205 and proximate to one or more corresponding stress concentration regions 220 of the substrate 205. As described in greater detail in connection with FIGS. 5 and 6, a stress concentration region 220 may correspond to a region of the substrate 205 that undergoes a stress and/or strain condition as a result of inserting the memory module 200 (e.g., the edge connector including the conductive pad) into a socket as part of testing the memory module 200 or as part of assembling a system including the memory module 200 (e.g., the system 100). Additionally, or alternatively, such a stress and/or strain condition may result from exposing the memory module 200 to a temperature that is elevated (or reduced) relative to an ambient condition surrounding the memory module 200.

As an example, the segment 215-a is over stress concentration region 220-a of the substrate 205, which may be proximate a corner of the substrate 205. As another example, the segment 215-b is over concentration region 220-b of the substrate 205, which is proximate an edge of the connector including the conductive pad 210 and/or proximate an edge of the substrate 205. As another example, the segment 215-c is over stress concentration region 220-c of the substrate, which is proximate an alignment slot 225 that may be used to align the memory module 200 (and or the edge connector including the pad 210) to a socket during insertion.

The photoelastic material may be a material having anisotropic optical properties. As described in greater detail in connection with FIG. 5, such properties may be conducive to determining a stress and/or strain condition in the substrate 205 based, at least in part, on a birefringence condition that is induced into a segment 215 as a result of a mechanical load. Additionally, or alternatively, the stress and/or strain condition (and/or the birefringence condition) may be resultant of testing the memory module 200 in a chamber at a temperature that is elevated (or reduced) relative to an ambient temperature. The photoelastic material may include resin, polycarbonate, polymethyl methacrylate, polyurethane, cellulose acetate, and/or glass, among other examples.

As described in greater detail in connection with FIGS. 5 and 6, the birefringence condition may be an optical condition that is detectable using an optical inspection tool. The photoelastic material may, for example, include portions having different refractive indices (e.g., anisotropic optical properties). When light enters the material, the light may split into polarized rays that travel at different speeds and exit the material at different angles and/or with varying phase shifts. Optical phenomena such as double refraction and/or phase retardation of the light exiting the material (e.g., features related to the birefringence condition) may be observable using the optical inspection tool and be indicative of a stress and/or a strain condition in the photoelastic material (and/or an underlying portion of the substrate 205).

Although FIG. 2 describes use of the segments 215 in the context of the memory device 145, the memory module 200, and the substrate 205, variations and/or permutations of the segments 215 (and techniques described elsewhere herein) may be used in in other applications that use another substrate and/or other semiconductor devices (a computing motherboard and/or a communications interface board, among other examples)

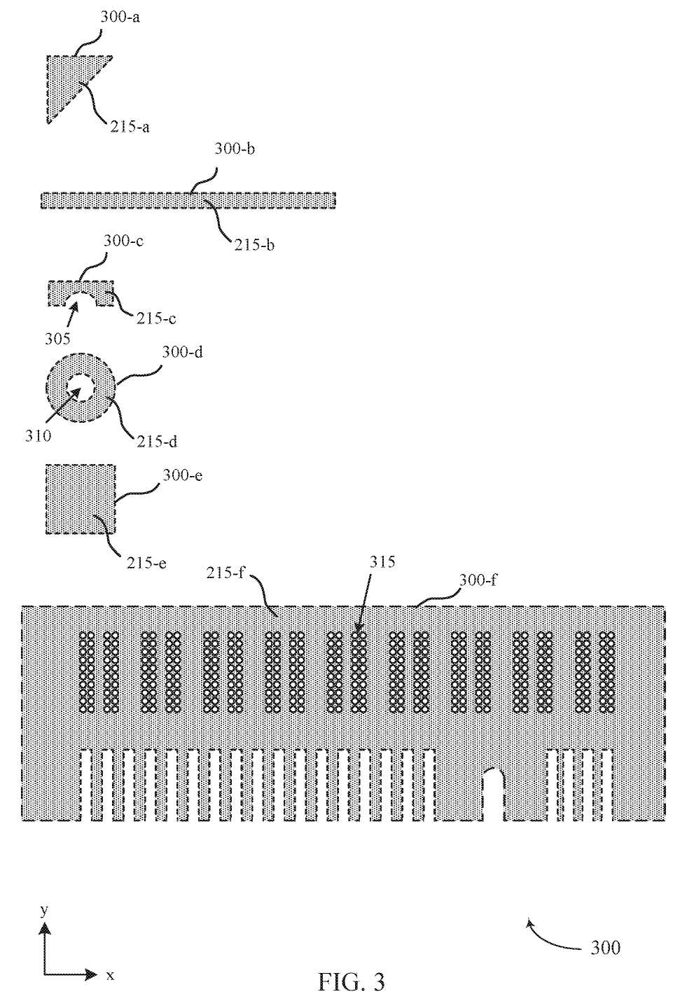

FIG. 3 shows example geometric profiles 300 that support stress and strain detection across a substrate of a semiconductor system using a photoelastic material in accordance with examples as disclosed herein. FIG. 3 is a plan view in an x-y plane corresponding to the x-y plane of FIG. 2. In some examples, one or more of the geometric profiles 300 (or features thereof) may be combined and/or integrated as part of a segment (e.g., segment 215) of the photoelastic material.

As shown in FIG. 3, segment 215-a includes geometric profile 300-a, which may correspond to an approximately triangular profile. An outline of geometric profile 300-a may include a combination of angled corners and/or approximately linear edges, among other examples.

As further shown in FIG. 3, segment 215-b includes geometric profile 300-b which may correspond to an approximately rectangular profile and/or a profile that approximates a parallelogram. An outline of geometric profile 300-b may include opposing edges that are elongated and approximately linear, among other examples.

As further shown in FIG. 3, segment 215-c includes geometric profile 300-c which may correspond to a notched profile. An outline of geometric profile 300-c may include a notch 305 that penetrates into an approximately linear edge, among other examples. Although shown in FIG. 3 to include a curved surface, in other examples the notch 305 may include approximately linear surfaces and/or surfaces with other contours.

As further shown in FIG. 3, segment 215-d includes geometric profile 300-d which may correspond to an approximately round profile and/or an approximately elliptical profile. Furthermore, and as shown in FIG. 3, the segment 215-d may include a through hole 310 (e.g., to accommodate an alignment pin, a fastener, or another type of hardware that might be used as part of fixturing a substrate to which the segment 215-d is coupled).

As further shown in FIG. 3, segment 215-e includes geometric profile 300-e which may correspond to an approximately square profile and/or a profile that approximates a parallelogram. An outline of geometric profile 300-e may include opposing edges that are of a same approximate length and that are approximately linear, among other examples. As further shown in FIG. 3, segment 215-f includes geometric profile 300-f which may correspond to an outline of a substrate (e.g., an outline of the substrate 205). In some examples, the segment 215-f may obviate a need for a solder mask over a substrate to which the segment 215-f is coupled. Said another way, the segment 215-f may be configured as a solder mask and directly coupled with an outer dielectric layer of the substrate. Furthermore, and as shown in FIG. 3, the segment 215-f may include openings 315 to accommodate interconnects used to couple a memory device (e.g., the memory device 145) to pads and/or traces of the substrate, or to accommodate an underfill material used to increase a robustness of a mechanical connection between the memory device and the substrate.

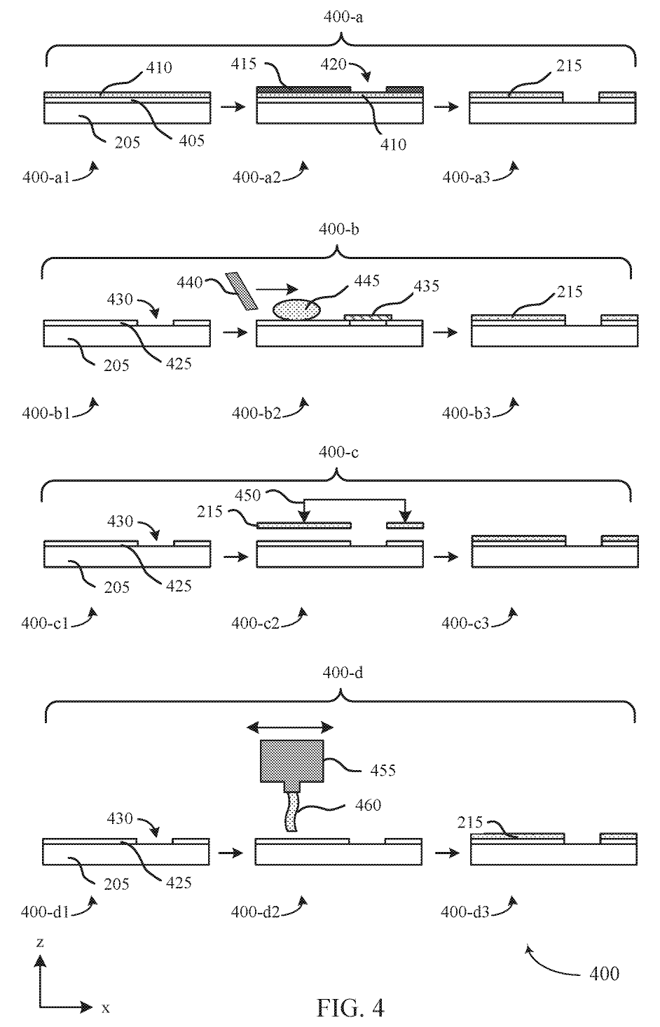

FIG. 4 shows example manufacturing operations 400 that support stress and strain detection across a substrate of a semiconductor system using a photoelastic material in accordance with examples as disclosed herein. FIG. 4 is a side view in an x-z plane showing at least a portion of the memory module 200. In some examples, the manufacturing operations 400 may be performed using semiconductor manufacturing tools located at a substrate manufacturer, a module assembly surface mount (SMT) line, an outsource assembly/test house (OSAT), and/or an original equipment manufacturer (OEM), among other examples. Additionally, or alternatively, one or more portions of the manufacturing operations 400 may support methods as described in connection with FIGS. 6 and/or 7.

FIG. 4 shows an example set of manufacturing operations 400-a that may be used to form a segment 215 (and/or a portion thereof). As shown in FIG. 4, the set of manufacturing operations 400-a may include manufacturing operation 400-a1. As part of manufacturing operation 400-a1, a semiconductor manufacturing tool (e.g., an incoming inspection tool or a photoresist dispense tool, among other examples) may receive the substrate 205. The substrate 205 may have a layer 405 of a solder mask material over and/or on the substrate 205, and a layer 410 of photoelastic material may be over and/or on the layer 405.

As shown in FIG. 4, the manufacturing operations 400-a may further include manufacturing operation 400-a2. As part of manufacturing operation 400-a2, a set of one or more semiconductor manufacturing tools (e.g., a photoresist dispense tool, an exposure tool, and/or a develop tool, among other examples) may perform a lithography operation that forms a patterned layer 415 of a photoresist material over and/or on the layer 410, including an opening 420 that exposes a portion of the layer 410.

As shown in FIG. 4, the manufacturing operations 400-a may further include manufacturing operation 400-a3. As part of manufacturing operation 400-a3, a semiconductor manufacturing tool (e.g., an etch tool) may, using the patterned layer 415 as a mask, perform an etch operation that removes the exposed portion of the layer 410, thereby forming at least a portion and/or an edge profile of a segment 215. The etch operation may further remove a portion of the layer 405 to expose a portion of the substrate 205. The exposed portion of the substrate 205 may correspond to a pad region of the substrate including a conductive pad (e.g., the conductive pad 210 as describe in connection with FIG. 2 or another conductive pad). Additionally, and as part of manufacturing operation 400-a3, a semiconductor manufacturing tool (e.g., an ashing tool) may remove the patterned layer 415 to reveal the segment 215.

FIG. 4 further shows an example set of manufacturing operations 400-b that may be used to form a segment 215 (and/or portions thereof). As shown in FIG. 4, the set of manufacturing operations 400-b may include manufacturing operation 400-b1. As part of manufacturing operation 400-b1, a semiconductor manufacturing tool (e.g., an incoming inspection tool or a screen printing tool, among other examples) may receive the substrate 205. The substrate 205 may have a patterned layer 425 of a solder mask material over and/or on the substrate 205. The patterned layer 425 may include an opening 430 that exposes a portion of the substrate 205. The exposed portion of the substrate 205 may correspond to a pad region of the substrate including a conductive pad (e.g., the conductive pad 210 as describe in connection with FIG. 2 or another conductive pad).

As shown in FIG. 4, the set of manufacturing operations 400-b may further include manufacturing operation 400-b2. As part of manufacturing operation 400-b2, a semiconductor manufacturing tool (e.g., a screen printing tool including a stencil 435 and a squeegee 440) may dispense a semi-liquid mixture 445 of a photoelastic material over and/or on the patterned layer 425.

As shown in FIG. 4, the set of manufacturing operations 400-b may further include manufacturing operation 400-b3. As part of manufacturing operation 400-b3, a semiconductor manufacturing tool (e.g., the screen printing tool including the squeegee 440) may spread the semi-liquid mixture 445 and form the segment 215.

FIG. 4 further shows an example set of manufacturing operations 400-c that may be used to form a segment 215 (and/or portions thereof). As shown in FIG. 4, the set of manufacturing operations 400-c may include manufacturing operation 400-c1. As part of manufacturing operation 400-c1, a semiconductor manufacturing tool (e.g., an incoming inspection tool or lamination tool, among other examples) may receive the substrate 205. The substrate 205 may have a patterned layer 425 of a solder mask material over and/or on the substrate 205. The patterned layer 425 may include an opening 430 that exposes a portion of the substrate 205. The exposed portion of the substrate 205 may correspond to a pad region of the substrate including a conductive pad (e.g., the conductive pad 210 as describe in connection with FIG. 2 or another conductive pad).

As shown in FIG. 4, the set of manufacturing operations 400-c may further include manufacturing operation 400-c2. As part of manufacturing operation 400-c2, a semiconductor manufacturing tool (e.g., a pick-and-place tool 450) may place a segment 215 that is pre-cut over the substrate 205.

As shown in FIG. 4, the set of manufacturing operations 400-c may further include manufacturing operation 400-c3. As part of manufacturing operations 400-c3, a semiconductor manufacturing tool (e.g., a lamination tool) may affix and/or join the segment 215 with the patterned layer 425.

FIG. 4 further shows an example set of manufacturing operations 400-d that may be used to form a segment 215 (and/or portions thereof). As shown in FIG. 4, the set of manufacturing operations 400-d may include manufacturing operation 400-d1. As part of manufacturing operation 400-d1, a semiconductor manufacturing tool (e.g., an incoming inspection tool or lamination tool, among other examples) may receive the substrate 205. The substrate 205 may have a patterned layer 425 of a solder mask material over and/or on the substrate 205. The patterned layer 425 may include an opening 430 that exposes a portion of the substrate 205. The exposed portion of the substrate 205 may correspond to a pad region of the substrate including a conductive pad (e.g., the conductive pad 210 as describe in connection with FIG. 2 or another conductive pad).

As shown in FIG. 4, the set of manufacturing operations 400-d may further include manufacturing operation 400-d2. As part of manufacturing operation 400-d2, a semiconductor manufacturing tool 455 (e.g., a three-dimensional (3D) printing tool) may use additive manufacturing techniques that dispense a liquid mixture 460 including a photoelastic material over and/or on the patterned layer 425.

As shown in FIG. 4, the set of manufacturing operations 400-d may further include manufacturing operation 400-d3. As part of manufacturing operations 400-d3, a semiconductor manufacturing tool (e.g., a curing tool) may cure the liquid mixture 460 to form a segment 215.

Although the manufacturing operations 400 of FIG. 4 are shown and described in the context of forming a segment 215 on a layer of a solder mask material (e.g., the layer 405 and/or the patterned layer 425), one or more portions of the manufacturing operations 400 may be used to form a segment 215 on a layer of another material. For example, one or more portions of the manufacturing operations 400 may be used to form a segment 215 (or portion thereof) on an outer dielectric layer (e.g., a top layer) of the substrate 205 (and obviate use of the layer 405 and/or the patterned layer 425).

Furthermore, and although the manufacturing operations 400 are shown and described in the context of forming a segment 215 over and/or on the substrate 205 prior the substrate 205 being populated with one or more semiconductor device (e.g., the memory device 145), in some examples one or more of the manufacturing operations 400 may occur after the substrate 205 is populated with the semiconductor devices. For example, one or more of the manufacturing operations 400 may occur after a surface mount (SMT) operation places the semiconductor devices on the substrate 205 (and couples the semiconductor devices with the substrate 205).

FIG. 5 shows an example socketing operation 500 that supports stress and strain detection across a substrate of a semiconductor system using a photoelastic material in accordance with examples as disclosed herein. FIG. 5 is a plan view in an x-y plane corresponding to the x-y plane of FIG. 2. In some examples, the socketing operation 500 may be an operation that is performed during testing and/or qualification of the memory module 200 in a lab environment. In some other examples, the socketing operation 500 may be an operation that is performed in a high volume manufacturing (HVM) environment during final assembly of a system that includes the memory module 200 (e.g., the system 100 as described in connection with FIG. 1).

As shown in FIG. 5, an edge connector of the memory module 200 (e.g., an edge connector including the pad 210) is inserted into a socket 505. Inserting the edge connector the socket 505 may communicatively couple the memory module 200 with electronic circuitry used to test functionality the memory module 200 and/or operate the memory module 200.

In some examples, insertion of the memory module 200 into the socket 505 may be a manual operation performed by an operator. In other examples, and as described in greater detail in connection with FIG. 6, insertion of the memory module 200 into the socket may be an automated operation performed by a semiconductor manufacturing tool (an automated testing equipment (ATE) tool, among other examples).

In some examples, a mechanical load may be associated with a force used to insert the memory module 200 into the socket 505. In such examples, the force may induce a tensile stress, a compressive stress, and/or a torsional stress to one or more stress concentration regions 220 of the substrate 205. Additionally, or alternatively, a mechanical load may be associated with a thermal condition used to test the memory module 200 at a temperature that is elevated or reduce relative to an ambient condition, thereby causing thermal stresses and/or strains within the module 200. The aforementioned stresses, whether induced by the force used to insert the memory module 200 into the socket 505 or the thermal condition, may induce a birefringence condition 510 in a segment 215 that is over and/or on the substrate 205.

For example, and shown in FIG. 5, the birefringence condition 510 may be induced into the segment 215-a that is over and/or on the stress concentration region 220-a of the memory module 200. As described in greater detail in connection with FIG. 6, the birefringence condition 510 may be detected using an optical inspection tool. In some examples, detection and/or analysis of the birefringence condition 510 may be used to adjust a vector associated with the mechanical load (e.g., a magnitude, a direction, or a torsion associated with the mechanical load) to alleviate the stress and/or strain condition. Additionally, or alternatively, detection and/or analysis of the birefringence condition 510 may be used to adjust a temperature of an environment surrounding the memory module 200.

The birefringence condition 510, which may be detectable by an optical inspection tool as described in greater detail in connection with FIG. 6, may include at least one portion 515 corresponding to a group of light waves exiting the segment 215-a at a first angle and/or a first phase. Additionally, or alternatively, the birefringence condition 510 may include at least one portion 520 corresponding to another group of light waves exiting the segment 215-a at a second angle and/or a second phase.

FIG. 6 shows an example manufacturing line 600 that supports stress and strain detection across a substrate of a semiconductor system using a photoelastic in accordance with examples as disclosed herein. In some examples, one or more portions of manufacturing line 600 may support a testing and/or qualification lab environment. In some other examples, one or more portions of the manufacturing line 600 may support an HVM environment such as a module SMT manufacturing line.

As shown in FIG. 6, the manufacturing line 600 may include one or more module assembly tool(s) 605. The module assembly tool(s) 605 may include one or more semiconductor manufacturing tools used to fabricate a memory module (e.g., the memory module 200) and/or portions thereof. For example, the module assembly tool(s) 605 may include one or more semiconductor manufacturing tools used to fabricate a substrate (e.g., the substrate 205 including the segment 215) as described in connection with FIG. 4 and/or one or more SMT tools used to place semiconductor devices (e.g., the memory device 145) on the substrate.

As further shown in FIG. 6, the manufacturing line 600 may include an ATE tool 610 and an optical inspection tool 615. In some examples, the ATE tool 610 includes a socket (e.g., the socket 505) that is coupled with test circuitry configured for testing functionality of the memory module. The ATE tool 610 may include mechanical linkages and/or automation (pneumatics, stepper motors, sensors, and/or other automatable components) that are configured to provide a mechanical load used to insert the memory module into the socket. In some examples, and for quality and/or reliability testing purposes, the ATE tool 610 may further include an environmental test chamber to enable testing of the memory module at a temperature that is elevated or reduced relative to an ambient temperature.

The ATE tool 610 may further include a processor and a non-transitory computer-readable medium (CRM) storing instructions that are configured to, upon execution by the processor, cause the mechanical linkages and/or automation to provide the mechanical load and insert the memory module into the socket. The instructions may further be configured to cause the ATE tool 610 to monitor one or more aspects of the mechanical load. The instructions may further be configured to adjust and/or monitor a temperature of the environmental test chamber.

The optical inspection tool 615 (e.g., a polarized light microscope, a polariscope, interferometer, ellipsometer, optical compensator, spectrometer, laser-based detector, or other optical inspection tool that is suitable for detecting a birefringence condition) may be communicatively coupled with the ATE tool 610. During insertion of the memory module into the socket, the optical inspection tool 615 may detect and/or capture a birefringence condition (e.g., the birefringence condition 510 as described in connection with FIG. 5), and provide information related to the birefringence condition (e.g., an image such as a bitmap corresponding the birefringence condition) to the ATE tool 610.

In some examples, the processor of the ATE tool 610 may execute instructions stored in the non-transitory CRM to evaluate and/or analyze the information to determine a stress and/or strain condition in the memory module. Based at least in part on the stress and/or strain condition, the processor may determine to adjust one or more settings controlling a vector associated with the mechanical load (e.g., a magnitude, a direction, or a torsion associate with the mechanical load), thereby alleviating at least a portion of the stress condition (and reducing a potential for cracking and/or other defects in the memory module) that may be caused by a mechanical load. Additionally, or alternatively, the processor may determine to adjust one or more settings controlling a temperature of the environmental chamber, thereby alleviating at least a portion of the stress condition that may be caused by a thermal load.

As shown in FIG. 6, the manufacturing line 600 may further include one or more finished goods tool(s) 620. The finished goods tool(s) 620 may include one or more semiconductor manufacturing tools used to label and/or package the memory module, among other examples. In some examples, the memory module may be provided to the finished goods tool(s) 620 after testing by the ATE tool 610.

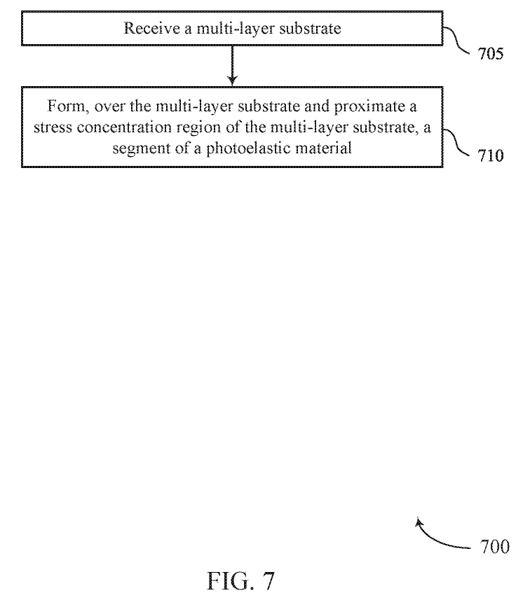

FIG. 7 shows a flowchart illustrating a method 700 that supports stress and strain detection across a substrate of a semiconductor system using a photoelastic in accordance with examples as disclosed herein. The operations of method 700 may be implemented by a one or more semiconductor manufacturing tools and/or components as described herein. For example, the operations of method 700 may be performed by one or more semiconductor manufacturing tools as described with reference to FIG. 4. In some examples, a semiconductor manufacturing tool may execute a set of instructions to control the functional elements of the device to perform the described functions. Additionally, or alternatively, the semiconductor manufacturing tool may perform aspects of the described functions using special-purpose hardware.

At 705, the method may include receiving a multi-layer substrate. In some examples, aspects of the operations of 705 may be performed by a semiconductor manufacturing tool (e.g., an incoming inspection tool, a photoresist dispense tool, a screen printing tool, or lamination tool) as describe with reference to FIG. 4

At 710, the method may include forming, over the multi-layer substrate and proximate a stress concentration region of the multi-layer substrate, a segment of a photoelastic material. In some examples, aspects of the operations of 710 may be performed by one or more semiconductor manufacturing tools (e.g., a photoresist dispense tool, an exposure tool, a develop tool, an etch tool, a screen printing tool, a lamination tool, or a 3D printing tool) as described with reference to FIG. 4.

In some examples, an apparatus as described herein may perform a method or methods, such as the method 700. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for receiving a multi-layer substrate and forming, over the multi-layer substrate and proximate a stress concentration region of the multi-layer substrate, a segment of a photoelastic material.

Aspect 2: The method, apparatus, or non-transitory computer-readable medium of aspect 1, where forming the segment includes placing a pre-cut onto segment of the photoelastic material over the stress concentration region.

Aspect 3: The method, apparatus, or non-transitory computer-readable medium of any of aspects 1 through 2, where forming the segment includes printing the segment over the stress concentration region using a screen printing operation.

Aspect 4: The method, apparatus, or non-transitory computer-readable medium of any of aspects 1 through 3, where forming the segment includes printing the segment over the stress concentration region using an additive manufacturing operation.

Aspect 5: The method, apparatus, or non-transitory computer-readable medium of any of aspects 1 through 4, where forming the segment over the stress concentration region includes using a photolithography operation.

Aspect 6: The method, apparatus, or non-transitory computer-readable medium of any of aspects 1 through 5, further including operations, features, circuitry, logic, means, or instructions, or any combination thereof for placing a semiconductor device on the multi-layer substrate prior to forming the segment of the photoelastic material.

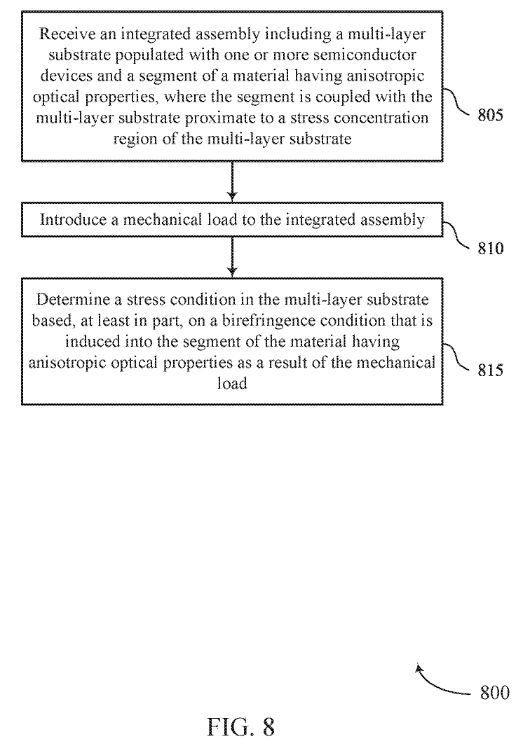

FIG. 8 shows a flowchart illustrating a method 800 that supports stress and strain detection across a substrate of a semiconductor system using a photoelastic in accordance in accordance with examples as disclosed herein. The operations of method 800 may be implemented by one or more semiconductor manufacturing tools and/or components as described herein. For example, the operations of method 800 may be performed by semiconductor manufacturing tools as described with reference to FIG. 6. In some examples, a semiconductor manufacturing tool may execute a set of instructions to control the functional elements of the device to perform the described functions. Additionally, or alternatively, the semiconductor manufacturing tool may perform aspects of the described functions using special-purpose hardware.

At 805, the method may include receiving an integrated assembly including a multi-layer substrate populated with one or more semiconductor devices and a segment of a material having anisotropic optical properties, where the segment is coupled with the multi-layer substrate proximate to a stress concentration region of the multi-layer substrate. In some examples, aspects of the operations of 805 may be performed by a semiconductor manufacturing tool (e.g., the ATE tool 610) as described with reference to FIG. 6.

At 810, the method may include introducing a mechanical load to the integrated assembly. In some examples, aspects of the operations of 810 may be performed by a semiconductor manufacturing tool (e.g., the ATE tool 610) as described with reference to FIG. 6.

At 815, the method may include determining a stress condition in the multi-layer substrate based, at least in part, on a birefringence condition that is induced into the segment of the material having anisotropic optical properties as a result of the mechanical load. In some examples, aspects of the operations of 815 may be performed by a semiconductor manufacturing tool (e.g., the ATE tool 610 and/or the optical inspection tool 615) as described with reference to FIG. 6.

In some examples, an apparatus as described herein may perform a method or methods, such as the method 800. The apparatus may include features, circuitry, logic, means, or instructions (e.g., a non-transitory computer-readable medium storing instructions executable by a processor), or any combination thereof for performing the following aspects of the present disclosure:

Aspect 7: A method, apparatus, or non-transitory computer-readable medium including operations, features, circuitry, logic, means, or instructions, or any combination thereof for receiving an integrated assembly including a multi-layer substrate populated with one or more semiconductor devices and a segment of a material having anisotropic optical properties, where the segment is coupled with the multi-layer substrate proximate to a stress concentration region of the multi-layer substrate; introducing a mechanical load to the integrated assembly; and determining a stress condition in the multi-layer substrate based, at least in part, on a birefringence condition that is induced into the segment of the material having anisotropic optical properties as a result of the mechanical load.

Aspect 8: The method, apparatus, or non-transitory computer-readable medium of aspect 7, where inserting an edge connector of the multi-layer substrate into a socket.

Aspect 9: The method, apparatus, or non-transitory computer-readable medium of any of aspects 7 through 8, where detecting the birefringence condition using a polariscope.

Aspect 10: The method, apparatus, or non-transitory computer-readable medium of any of aspects 7 through 9, further including operations, features, circuitry, logic, means, or instructions, or any combination thereof for adjusting a setting controlling a vector of the mechanical load based, at least in part, on the stress condition.

Aspect 11: The method, apparatus, or non-transitory computer-readable medium of aspect 10, where adjusting a setting controlling a magnitude of the mechanical load; adjusting a setting controlling a direction of the mechanical load; and adjusting a setting controlling a torsion of the mechanical load.

It should be noted that the aspects described herein describe possible implementations, and that the operations and the steps may be rearranged or otherwise modified and that other implementations are possible. Further, portions from two or more of the methods may be combined.

An apparatus is described. The following provides an overview of aspects of the apparatus as described herein:

Aspect 12: A memory system, including: one or more memory devices; a multi-layer substrate coupled with the one or more memory devices; and one or more segments of a material having anisotropic optical properties positioned over the multi-layer substrate and proximate to one or more corresponding stress concentration regions of the multi-layer substrate.

Aspect 13: The memory system of aspect 12, where at least one segment of the one or more segments of the material having anisotropic optical properties is directly coupled with a solder mask that is positioned over the multi-layer substrate.

Aspect 14: The memory system of any of aspects 12 through 13, where at least one segment of the one or more segments of the material having anisotropic optical properties is configured as a solder mask and directly coupled with an outer dielectric layer of the multi-layer substrate.

Aspect 15: The memory system of any of aspects 12 through 14, where the one or more segments of the material having anisotropic properties include: a segment positioned over a region that is proximate an edge of the multi-layer substrate, the region proximate to a connector of the multi-layer substrate.

Aspect 16: The memory system of any of aspects 12 through 15, where the one or more segments of the material having anisotropic properties include: a segment positioned over a region that is proximate to a corner of the multi-layer substrate.

Aspect 17: The memory system of any of aspects 12 through 16, where the one or more segments of the material having anisotropic optical properties include: a segment positioned over a region that is proximate to a discontinuity of the multi-layer substrate.

Aspect 18: The memory system of any of aspects 12 through 17, where the material includes a photoelastic material.

Aspect 19: The memory system of aspect 18, where the photoelastic material is selected from a group consisting of epoxy resin; polycarbonate; polymethyl methacrylate; polyurethane; cellulose acetate; and glass.

Aspect 20: The memory system of any of aspects 12 through 19, where at least one of the one or more segments includes: an approximately rectangular shape; an approximately triangular shape; or an approximately elliptical shape.

Aspect 21: The memory system of any of aspects 12 through 20, where an outline of at least one of the one or more segments includes a portion having: a curved profile; an approximately linear profile; a stepped profile; or a notched profile.

Aspect 22: The memory system of any of aspects 12 through 21, where the memory system is configured as: a solid state drive including at least one NAND memory device; or a memory module including at least one dynamic random access memory device.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

The terms “electronic communication,” “conductive contact,” “connected,” and “coupled” may refer to a relationship between components that supports the flow of signals between the components. Components are considered in electronic communication with (e.g., in conductive contact with, connected with, coupled with) one another if there is any electrical path (e.g., conductive path) between the components that can, at any time, support the flow of signals (e.g., charge, current, voltage) between the components. A conductive path between components that are in electronic communication with each other (e.g., in conductive contact with, connected with, coupled with) may be an open circuit or a closed circuit based on the operation of the device that includes the connected components. A conductive path between connected components may be a direct conductive path between the components or may be an indirect conductive path that includes intermediate components, such as switches, transistors, or other components. In some examples, the flow of signals between the connected components may be interrupted for a time, for example, using one or more intermediate components such as switches or transistors. Additionally, or alternatively, and depending on a context, “coupled” may refer to a mechanical coupling (with or without a flow of signals between components).

The terms “layer” and “level” may refer to an organization (e.g., a stratum, a sheet) of a geometrical structure (e.g., relative to a substrate). Each layer or level may have three dimensions (e.g., height, width, and depth) and may cover at least a portion of a surface. For example, a layer or level may be a three dimensional structure where two dimensions are greater than a third, e.g., a thin-film. Layers or levels may include different elements, components, or materials. In some examples, one layer or level may be composed of two or more sublayers or sublevels.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, instructions (e.g., code, software, firmware, logic) executed by a processing system (e.g., one or more processors, one or more controllers, control circuitry, processing circuitry, logic circuitry), or any combination thereof that is configured to cause a respective apparatus, device, or system to perform the described functions. If implemented as instructions executed by a processing system, the functions may be stored on or transmitted over as one or more instructions on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof, that are configured to cause the performance of the functions described herein. A processor may be an example of a microprocessor, a controller, a microcontroller, a state machine, or other types of processors. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, which can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or one or more processors.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A memory system, comprising:
one or more memory devices;
a multi-layer substrate coupled with the one or more memory devices; and
one or more segments of a material having anisotropic optical properties positioned over the multi-layer substrate and proximate to one or more corresponding stress concentration regions of the multi-layer substrate.

2. The memory system of claim 1, wherein at least one segment of the one or more segments of the material having anisotropic optical properties is directly coupled with a solder mask that is positioned over the multi-layer substrate.

3. The memory system of claim 1, wherein at least one segment of the one or more segments of the material having anisotropic optical properties is configured as a solder mask and directly coupled with an outer dielectric layer of the multi-layer substrate.

4. The memory system of claim 1, wherein the one or more segments of the material having anisotropic properties comprise:
a segment positioned over a region that is proximate an edge of the multi-layer substrate, the region proximate to a connector of the multi-layer substrate.

5. The memory system of claim 1, wherein the one or more segments of the material having anisotropic properties comprise:
a segment positioned over a region that is proximate to a corner of the multi-layer substrate.

6. The memory system of claim 1, wherein the one or more segments of the material having anisotropic optical properties comprise:
a segment positioned over a region that is proximate to a discontinuity of the multi-layer substrate.

7. The memory system of claim 1, wherein the material comprises a photoelastic material.

8. The memory system of claim 7, wherein the photoelastic material is selected from a group consisting of:
epoxy resin;
polycarbonate;
polymethyl methacrylate;
polyurethane;
cellulose acetate; and
glass.

9. The memory system of claim 1, wherein at least one of the one or more segments comprises:
an approximately rectangular shape;
an approximately triangular shape; or
an approximately elliptical shape.

10. The memory system of claim 1, wherein an outline of at least one of the one or more segments comprises a portion having:
a curved profile;
an approximately linear profile;
a stepped profile; or
a notched profile.

11. The memory system of claim 1, wherein the memory system is configured as:
a solid state drive comprising at least one NAND memory device; or
a memory module comprising at least one dynamic random access memory device.

12. A method, comprising:
receiving a multi-layer substrate; and
forming, over the multi-layer substrate and proximate a stress concentration region of the multi-layer substrate, a segment of a photoelastic material.

13. The method of claim 12, wherein forming the segment of the photoelastic material includes placing a pre-cut segment of the photoelastic material over the stress concentration region.

14. The method of claim 12, wherein forming the segment of the photoelastic material includes printing the segment over the stress concentration region using a screen printing operation.

15. The method of claim 12, wherein forming the segment of the photoelastic material includes printing the segment over the stress concentration region using an additive manufacturing operation.

16. The method of claim 12, wherein forming the segment of the photoelastic material includes forming the segment over the stress concentration region using a photolithography operation.

17. The method of claim 12, further comprising:
placing a semiconductor device on the multi-layer substrate prior to forming the segment of the photoelastic material.

18. A method, comprising:
receiving an integrated assembly including a multi-layer substrate populated with one or more semiconductor devices and a segment of a material having anisotropic optical properties, wherein the segment is coupled with the multi-layer substrate proximate to a stress concentration region of the multi-layer substrate;
introducing a mechanical load to the integrated assembly; and
determining a stress condition in the multi-layer substrate based, at least in part, on a birefringence condition that is induced into the segment of the material having anisotropic optical properties as a result of the mechanical load.

19. The method of claim 18, wherein introducing the mechanical load includes inserting an edge connector of the multi-layer substrate into a socket.

20. The method of claim 18, wherein determining the stress condition includes detecting the birefringence condition using an optical inspection tool selected from a group consisting of:
a polarized light microscope,
a polariscope,
an interferometer,
an optical compensator,
a spectrometer; and
a laser-based detector.

21. The method of claim 18, further comprising:
adjusting a setting controlling a vector of the mechanical load based, at least in part, on the stress condition.

22. The method of claim 21, wherein adjusting the setting controlling the vector includes at least one of:
adjusting a setting controlling a magnitude of the mechanical load;
adjusting a setting controlling a direction of the mechanical load; or
adjusting a setting controlling a torsion of the mechanical load.
